(19) United States
(12) Patent Application Publication
(10) Pub. No.: US 2026/0231521 A1
(43) Pub. Date: Aug. 6, 2026

(54) INTEGRATED CIRCUIT DEVICE AND MANUFACTURING METHOD THEREOF

(71) Applicant: TAIWAN SEMICONDUCTOR MANUFACTURING COMPANY, LTD., Hsinchu (TW)

(72) Inventors: Szu-Hua CHEN, Tainan City (TW); Cheng-Ming LIN, Kaohsiung City (TW); Kai-Chieh YANG, New Taipei City (TW); Wei-Yen WOON, Taoyuan City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 19/047,410

(22) Filed: Feb. 6, 2025

(51) Int. Cl. H10D 84/85; H10D 84/01; H10D 84/83

(52) U.S. Cl. CPC H10D 84/856; H10D 84/0177; H10D 84/0181; H10D 84/0188; H10D 84/8311; H10D 84/83135; H10D 84/83138; H10D 84/832; H10D 84/851

(57) ABSTRACT

A method for manufacturing an integrated circuit device is provided. The method includes forming a bottom epitaxial stack comprising a bottom channel layer and a bottom sacrificial layer, a middle sacrificial layer, and a top epitaxial stack comprising a top channel layer and a top sacrificial layer; patterning the top and bottom epitaxial stacks and the middle sacrificial layer into a fin; replacing the middle sacrificial layer with a first isolation layer; removing the bottom and top sacrificial layers to expose surfaces of the bottom and top channel layers; forming a plurality of interfacial layers over the exposed surfaces of the bottom and top channel layers; depositing a self-assembled monolayer over a surface of the isolation layer; with the self-assembled monolayer in place, selectively depositing a high-k dielectric layer over surfaces of the interfacial layers; and depositing a gate metal layer around the high-k dielectric layer.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET structure in accordance with some embodiments of the present disclosure.

FIGS. 2-13C illustrate schematic views of intermediate stages in the manufacture of an integrated circuit device in accordance with some embodiments of the present disclosure.

FIGS. 14A-17B illustrate schematic views of intermediate stages in the manufacture of an integrated circuit device in accordance with some embodiments of the present disclosure.

FIGS. 18A-18C are chemical formulas of a self-assembled monolayer having a higher affinity to oxide than to SiOCN in accordance with some embodiments of the present disclosure.

FIGS. 19A-19B are chemical formula of a self-assembled monolayer having a higher affinity to SiOCN than to oxide in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices (e.g., planar transistors) that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a GAA transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents. Stacked transistor structures, such as complementary field effect transistors (CFETs) including vertically stacked p-type FETs and n-type FETs, can provide further reduced footprint and density improvement for advanced IC technology nodes (particularly as IC technology nodes advance to 3 nm (N3) and below).

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

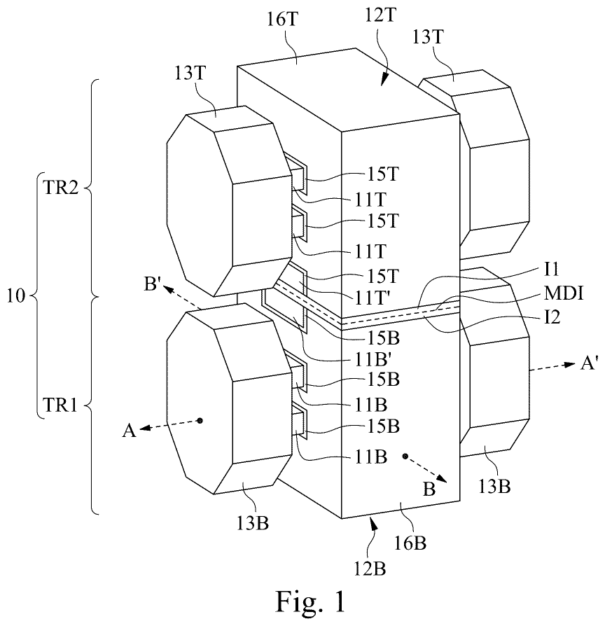

FIG. 1 is a perspective view of an example CFET structure 10 in accordance with some embodiments of the present disclosure. In some embodiments of the present disclosure, a CFET structure 10 includes a bottom transistor TR1 and a top transistor TR2 vertically stacked over the bottom transistor TR1. In some embodiments, the bottom transistor TR1 and the top transistor TR2 are GAA FET transistors. In some embodiments, the bottom transistor TR1 has a first conductivity type (e.g., n-type) and the top transistor TR2 has a second conductivity type (e.g., p-type) different from the first conductivity type. The bottom transistor TR1 includes bottom semiconductor channel layers 11B disposed one above another, a bottom gate structure 12B wrapping around each of the bottom semiconductor channel layers 11B, and bottom source/drain epitaxy structures 13B on opposite sides of each of the bottom semiconductor channel layers 11B. The top transistor TR2 includes top semiconductor channel layers 11T vertically stacked one above another, a top metal gate structure 12T wrapping around each of the top semiconductor channel layers 11T, and top source/drain epitaxy structures 13T on opposite sides of each of the top semiconductor channel layers 11T. The bottom gate structure 12B may include a high-k gate dielectric layer 15B and one or more gate metal layers 16B around the high-k gate dielectric layer 15B. The top gate structure 12T may include a high-k gate dielectric layer 15T, and one or more gate metal layers 16T.

In some embodiments, the bottom transistor TR1 and the top transistor TR2 are electrically isolated from each other by a middle isolation layer MDI. For example, the middle isolation layer MDI has a channel isolation portion I1 between the dummy channel layers 11B′ and 11T′ and a gate isolation portion I2 between the gate metal layers 16B and 16T.

In the CFET structure, a dummy bottom semiconductor channel layers 11B′ and a dummy top semiconductor channel layers 11T′ are respectively located on bottom and top surfaces of the middle isolation layer MDI. Little or no high-k gate dielectric materials is located at sidewalls of the channel isolation portion I1 and the gate isolation portion I2. For example, the high-k gate dielectric layers 15B and 15T surrounding the dummy bottom semiconductor channel layers 11B′ and the dummy top semiconductor channel layers 11T′ are spaced apart from each other. With the configuration, little or no fringing field would be formed between the metal gate for p-type transistor and the metal gate for n-type transistor.

FIG. 1 further illustrates reference cross-sections that are used in later figures. Cross-section A-A is perpendicular to cross-sections A-A and B-B and is parallel to the direction of current flow between the epitaxial source/drain structures 13B of the bottom transistor TR1 and the direction of current flow between the epitaxial source/drain structures 13T of the top transistor TR2. Cross-section B-B is along a longitudinal axis of gate structures 12B, 12T and in a direction, for example, perpendicular to the direction of current flow between the epitaxial source/drain structures 13B of the bottom transistor TR1 and the direction of current flow between the epitaxial source/drain structures 13T of the top transistor TR2. Subsequent figures refer to these reference cross-sections for clarity.

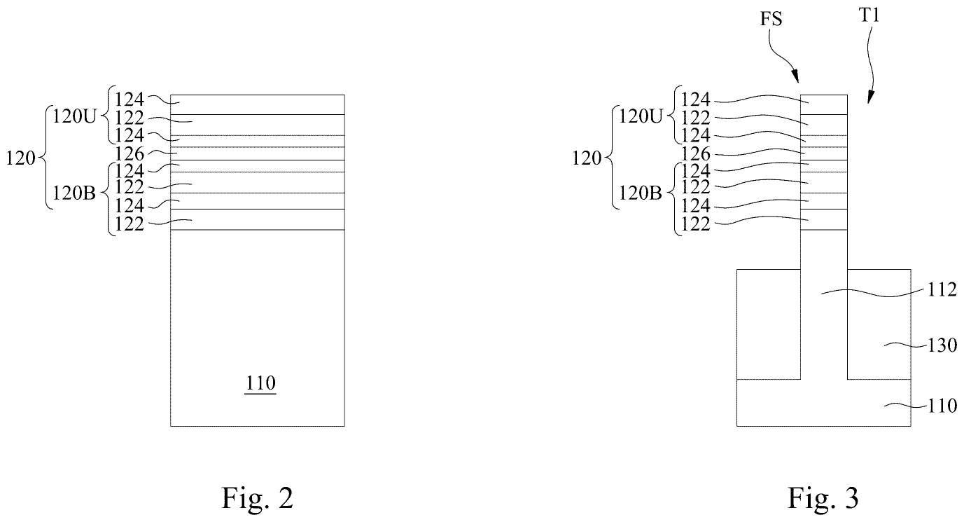

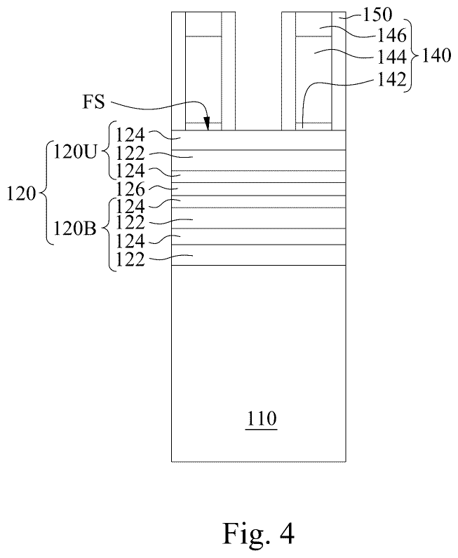

FIGS. 2-13C illustrate schematic views of intermediate stages in the manufacture of an integrated circuit device in accordance with some embodiments of the present disclosure. FIGS. 2, 4, 5, 6, 7A, 8A, 9A, 10A, 11A, 12A, and 13A are cross-sectional views of the integrated circuit device (e.g., taken along a fin direction, e.g., cross-section A-A in FIG. 1) at various manufacturing stages in accordance with some embodiments. FIGS. 3, 7B, 8B, 9B, 10B, 11B, 12B, and 13B are cross-sectional views of the integrated circuit device (e.g., taken along a gate direction, e.g., cross-section B-B in FIG. 1) at various manufacturing stages in accordance with some embodiments. It is understood that additional steps may be provided before, during, and after the steps shown in FIGS. 2-13C, and some of the steps described below can be replaced or eliminated for additional embodiments of the method. The order of the operations/processes may be interchangeable.

Reference is made to FIG. 2. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes a bottom epitaxial stack 120B, a sacrificial layer 126, and a top epitaxial stack 120T stacked over the substrate 110. Each of the bottom epitaxial stack 120B and the top epitaxial stack 120T includes at least one sacrificial layer 122 and at least one channel layer 124 stacked alternately over the substrate 110. In some embodiments, the layers 122-126 may include SiGe with various semiconductor compositions. For example, a Si concentration in the sacrificial layers 122 is less than a Si concentration in the channel layers 124, and a Si concentration in the sacrificial layers 126 is less than a Si concentration in the sacrificial layers 122. Stated differently, in some embodiments, a Ge concentration in the sacrificial layers 126 is greater than a Ge concentration in the sacrificial layers 122, and a Ge concentration in the sacrificial layers 122 is greater than a Ge concentration in the channel layers 124. For example, the channel layers 124 are SiₓGe₁₋ₓ, the sacrificial layers 122 are Si_{y}Ge_{1-y}, the sacrificial layers 126 are Si_{z}Ge_{1-z}, in which x, y, and z are in a range from 0 to 1, and x>y>z. However, other embodiments are possible including those that provide for the material/compositions having different oxidation rates and/or etch selectivity. In some embodiments where the sacrificial layers 122 and 126 include SiGe and the channel layers 124 include Si, the Si oxidation rate of the channel layers 124 is less than the SiGe oxidation rate of the sacrificial layers 122, and the Si oxidation rate of the sacrificial layers 122 is less than the SiGe oxidation rate of the sacrificial layers 126.

The channel layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 124 may be referred to as semiconductor channels in the context.

By way of example, epitaxial growth of the sacrificial layers 122, 126 and the channel layers 124 of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the sacrificial layers 122, 126 and the channel layers 124, include suitable semiconductor material, such as like Si, Ge, Sn, SiGe, GeSn, III-V semiconductor, the like, or the combination thereof. In some embodiments, the channel layers 124 may include a same semiconductor material as that substrate 110. In some embodiments, the epitaxially grown sacrificial layers 122 and 126 include a different material than the substrate 110. In some other embodiments, at least one of the sacrificial layers 122, 126 and the channel layers 124 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the sacrificial layers 122, 126, and the channel layers 124 may be chosen based on providing differing oxidation and/or etching selectivity properties.

In some embodiments, the sacrificial layers 122, 126, and the channel layers 124 are intrinsic semiconductor layers, which are not intentionally doped, for example, not having intentionally placed dopants, but rather having a doping resulting from process contaminants. In some embodiments, the sacrificial layers 122, 126, and the channel layers 124 are substantially dopant-free (i.e., having an extrinsic dopant concentration from about 0 cm⁻³ to about 1×10¹⁸ cm⁻³), where for example, no intentional doping is performed during the epitaxial growth process. In some alternative embodiments, the sacrificial layers 122, 126, and the channel layers 124 may be lightly doped for forming a device of a certain conductivity type. For example, for forming an n-type device, the sacrificial layers 122, 126, and the channel layers 124 may be lightly doped with p-type dopants with dopant concentration from about 0 cm⁻³ to about 1×10¹⁸ cm⁻³. For example, for forming a p-type device, the sacrificial layers 122, 126, and the channel layers 124 may be lightly doped with n-type dopants with dopant concentration from about 0 cm⁻³ to about 1×10¹⁸ cm⁻³.

Reference is made to FIG. 3. One or more semiconductor fins FS extending from the substrate 110 are formed. In various embodiments, each of the fins FS includes a substrate portion 112 formed from the substrate 110 and portions of each of the epitaxial layers of the epitaxial stack 120 including epitaxial layers 122-126. The fins FS may be fabricated using suitable processes including photolithography and etch processes. The photolithography process may include forming a photoresist layer (not shown) over a hard mask layer over the stack 120, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions through the hard mask layer, through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

Isolation structures 130 are formed in the trench T1 between the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material over the fins FS, followed by an etching back process. Through the etching back process, a top surface of the isolation structure 130 is lowered to a position lower than a bottommost surface of the epitaxial stack 120, such that the sacrificial layers 122 and 126 and the channel layers 124 are exposed.

Reference is made to FIG. 3. One or more dummy gate structures 140 are formed on the fins FS. The dummy gate structure 140 may include a gate dielectric 142 and a gate electrode 144. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a chemical vapor deposition (CVD) process, a sub-atmospheric CVD (SACVD) process, a FCVD process, an atomic layer deposition (ALD) process, a physical vapor deposition (PVD) process, or other suitable process. The gate electrode 144 may include polycrystalline silicon (polysilicon). In some embodiments, the materials of the dummy gate structure 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer, a gate electrode layer, and a mask layer, followed by a patterning process. For example, the patterning process includes a lithography process (e.g., photolithography or e-beam lithography) and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 140.

Gate spacers 150 are formed on opposite sidewalls of the dummy gate structures 140. The spacers 150 may be made of a dielectric material such as silicon oxide, silicon nitride, silicon carbide, silicon oxynitride, SiCN, silicon oxycarbide, SiOCN, and/or combinations thereof. In some embodiments, each of the spacers 150 includes a single layer or multiple layers. The gate spacers 150 may be formed by first depositing one or more conformal spacer material layers and subsequently etching back the one or more spacer material layers to form the gate spacers 150. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 150 on the vertical surfaces, such as the sidewalls of the dummy gate structures 140 and sidewalls of the fins FS.

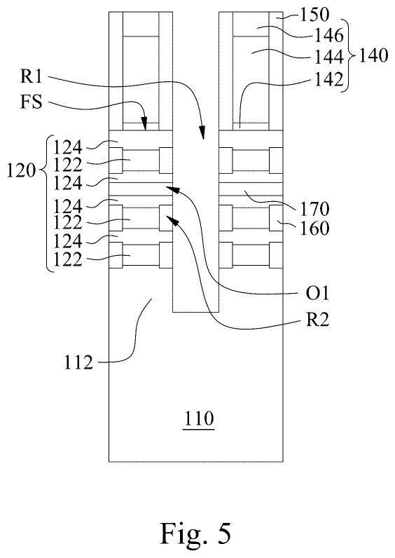

Reference is made to FIG. 4. After formation of the dummy gate structures 140 and the gate spacers 150, exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. After the anisotropic etching, end surfaces of the sacrificial layers 122 and the channel layers 124 are exposed by the recesses R1 and aligned with respective outermost sidewalls of the gate spacers 150, due to the anisotropic etching. In some embodiments, the anisotropic etching may be performed by a dry chemical etch (e.g., reactive-ion etching) with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The sacrificial layers 122 and 126 are laterally or horizontally recessed by using suitable selective etching process, resulting in lateral/sidewall recesses R2 and openings O1 vertically between corresponding layers 124. For example, end surfaces of the sacrificial layers 122 and 126 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The layers 122 may have a higher etch resistance to the selective etching process than that of the sacrificial layers 122 and 126. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 124 may not be not significantly etched by the process of laterally recessing the sacrificial layers 122 and 126. As a result, the layers 124 laterally extend past opposite end surfaces of the sacrificial layers 122.

In some embodiments, while the interlayer sacrificial layer 126 (referring to FIG. 3) has a higher germanium concentration than that of the sacrificial layers 122, the interlayer sacrificial layer 126 may have a lower etch resistance to the selective etching process than that of the sacrificial layers 122. For example, the selective etching process may remove an entirety of the interlayer sacrificial layer 126 (referring to FIG. 3), leave an opening O1 between the semiconductor layers 124 at the place of the interlayer sacrificial layer 126 (referring to FIG. 3).

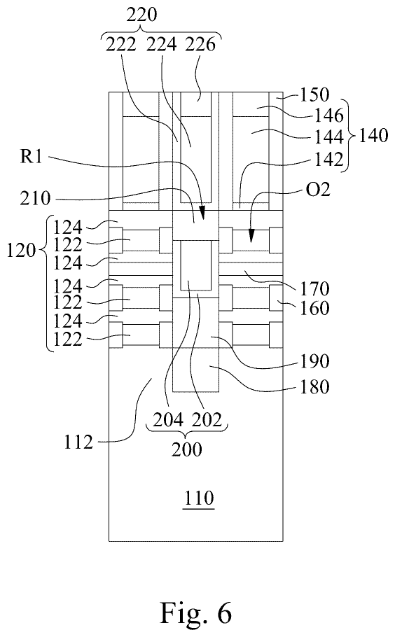

Reference is made to FIG. 5. An isolation layer 170 is formed in the opening O1. In some embodiments, the isolation layer 170 includes low-k dielectric materials, SiN, SiCN, SiOC, SiOCN or the like. Formation of the isolation layer 170 may include suitable CVD, ALD process, the like, or the combination thereof. The isolation layer 170 may serve to isolate a channel for p-type transistor from a channel for n-type transistor. In the context, the removal of the interlayer sacrificial layer 126 (referring to FIG. 3) and the formation of the isolation layer 170 in combination can be considered as replacing the interlayer sacrificial layer 126 (referring to FIG. 3) with the isolation layer 170.

Inner spacers 160 are formed in the recesses R2. Stated differently, the inner spacers 160 may be formed on opposite end surfaces of the laterally recessed sacrificial layers 122. The inner spacers 160 may include a low-k dielectric material, such as SiOₓ, SiON, SiOC, SiN, SiCN, or SiOCN. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 160 may include a single layer or multiple layers. The inner spacers 160 may serve to isolate metal gates from source/drain regions formed in subsequent processing.

In some embodiments, the inner spacers 160 and the isolation layer 170 are formed by depositing a same inner spacer material layer, followed by an anisotropic etching process to trim the deposited inner spacer material layer. Thus, the inner spacers 160 and the isolation layer 170 may include a same dielectric material. In some alternative embodiments, the inner spacers 160 and the isolation layer 170 are formed by different deposition process, and the inner spacers 160 and the isolation layer 170 may include different dielectric materials.

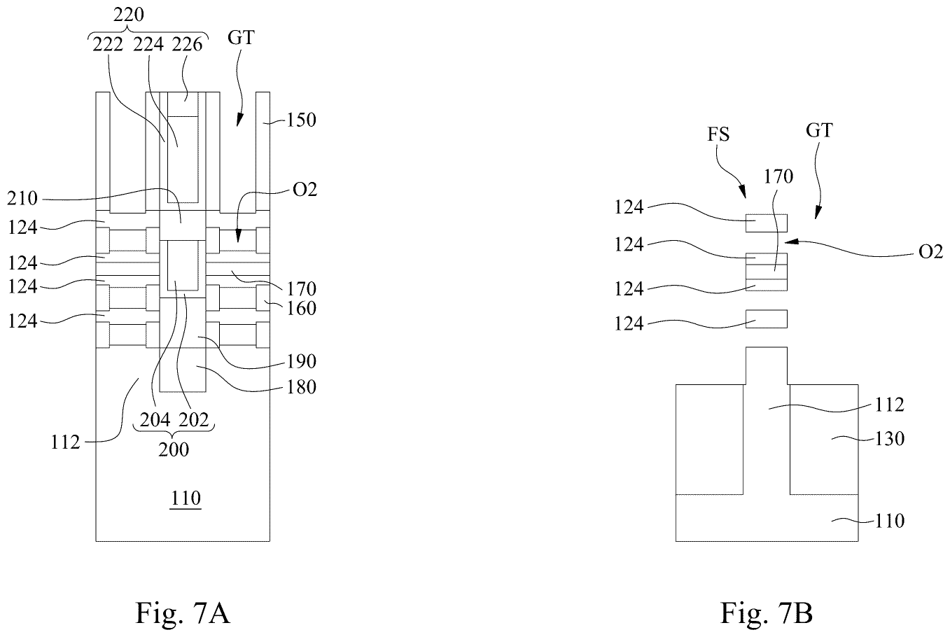

Reference is made to FIG. 6. Source/drain epitaxial structures 190 are formed in the recess R1, and in contact with opposite sides of the channel layers 124. In some embodiments, the source/drain epitaxial structures 190 may include Ge, Si, GaAs, AlGaAs, SiGe, GaAsP, SiP, or other suitable material. The source/drain epitaxial structures 190 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 190 are not in-situ doped, an implantation process (i.e., a junction implant process) is performed to dope the source/drain epitaxial structures 190. The source/drain epitaxial structures 190 may be formed by performing an epitaxial growth process that provides an epitaxial material on the exposed surfaces of the channel layers 124 and the substrate 110. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 124 and the substrate 110.

After the formation of the source/drain epitaxial structures 190, dielectric structures 200 are formed in the recess R1 and on the source/drain epitaxial structures 190. Each of the dielectric structure 200 may include an etch stop layer (ESL) 202 and an interlayer dielectric (ILD) layer 204 over the ESL 202. In some examples, the ESL layer 202 includes a silicon nitride layer, silicon oxide layer, a silicon oxynitride layer, and/or other suitable materials. The ESL layer 202 may be formed by plasma-enhanced chemical vapor deposition (PECVD) process and/or other suitable deposition or oxidation processes. In some embodiments, the ILD layer 204 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 202. The ILD layer 204 may be deposited by a CVD process or other suitable deposition technique.

Source/drain epitaxial structures 210 are formed in the recess R1, and in contact with opposite sides of the channel layers 124. In some embodiments, the source/drain epitaxial structures 210 may include Ge, Si, GaAs, AlGaAs, SiGe, GaAsP, SiP, or other suitable material. The source/drain epitaxial structures 210 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 210 are not in-situ doped, an implantation process (i.e., a junction implant process) is performed to dope the source/drain epitaxial structures 210. The source/drain epitaxial structures 210 may be formed by performing an epitaxial growth process that provides an epitaxial material on the exposed surfaces of the channel layers 124. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 124 and the substrate 110.

In some embodiments of the present disclosure, the source/drain epitaxial structures 210 has a conductive type opposite to that of the source/drain epitaxial structures 190. For example, the source/drain epitaxial structures 210 is a n-type source/drain epitaxial structure for an n-type device, and the source/drain epitaxial structures 190 is a p-type source/drain epitaxial structure for a p-type device. Alternatively, in some other embodiments, the source/drain epitaxial structures 210 is a p-type source/drain epitaxial structure for an p-type device, and the source/drain epitaxial structures 190 is a n-type source/drain epitaxial structure for a n-type device.

After the formation of the source/drain epitaxial structures 210, dielectric structures 220 are formed in the recess R1 and on the source/drain epitaxial structures 210. Each of the dielectric structure 220 may include an etch stop layer (ESL) 222, an interlayer dielectric (ILD) layer 224 over the ESL 222, a protection layer 226 over the ILD layer 226. In some examples, the ESL layer 222 includes a silicon nitride layer, silicon oxide layer, a silicon oxynitride layer, and/or other suitable materials. The ESL layer 222 may be formed by plasma-enhanced chemical vapor deposition (PECVD) process and/or other suitable deposition or oxidation processes. In some embodiments, the ILD layer 224 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the ESL layer 222. The ILD layer 224 may be deposited by a CVD process or other suitable deposition technique. In some examples, the protection layer 226 includes a silicon nitride layer, silicon oxide layer, a silicon oxynitride layer, and/or other suitable materials having a different etch selectivity than the ILD layer 224.

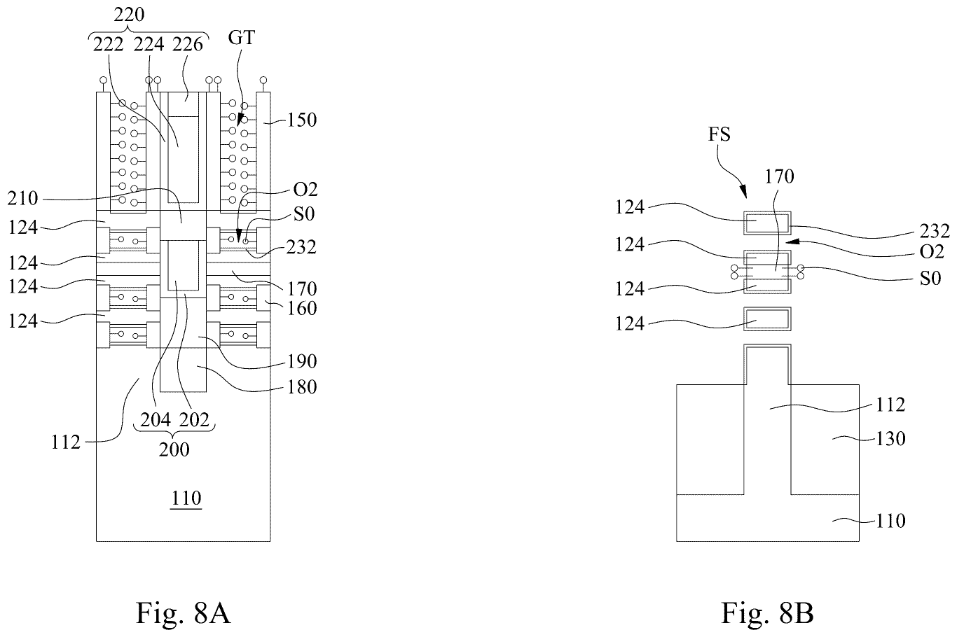

Reference is made to FIGS. 7A and 7B. The dummy gate structures 140 (referring to FIG. 6) is removed, followed by removing the sacrificial layers 122 (referring to FIG. 6). For example, the dummy gate structures 140 (referring to FIG. 6) are removed by using a selective etching process (e.g., selective dry etching, selective wet etching, or a combination thereof) that etches the materials in dummy gate structures 140 (referring to FIG. 6) at a faster etch rate than it etches other materials (e.g., the gate spacers 150, the ESL layer 222, and/or the protection layer 226), thus resulting in gate trenches GT between corresponding gate spacers 150. Subsequently, the sacrificial layers 122 (referring to FIG. 6) in the gate trenches GT are etched by using another selective etching process that etches the sacrificial layers 122 at a faster etch rate than it etches the layers 124 and the substrate portion 112, thus forming openings/spaces O2 between neighboring layers 124 and the substrate portion 112. The openings/spaces O2 may expose the sidewalls of the inner spacers 160. In this way, the channel layers 124 become nanosheets suspended over the substrate 110 and between the source/drain epitaxial structures 190, and the channel layers 124 become nanosheets suspended over the substrate 110 and between the source/drain epitaxial structures 210. This step is also called a channel release process. At this interim processing step, the openings/spaces O2 surrounding the nanosheets 124 may be filled with ambient environment conditions (e.g., air, nitrogen, etc). In some embodiments, the nanosheets 124 can be interchangeably referred to as nanowires, nanoslabs and nanorings, depending on their geometry. For example, in some other embodiments, the channel layers 124 may be trimmed to have a substantial rounded shape (i.e., cylindrical) due to the selective etching process for completely removing the sacrificial layers 122 (referring to FIG. 6). In that case, the resultant channel layers 124 can be called nanowires.

In some embodiments, the sacrificial layers 122 (referring to FIG. 6) are removed by using a selective dry etching process. In some embodiments, the sacrificial layers 122 (referring to FIG. 6) are SiGe and the channel layers 124 are silicon allowing for the selective removal of the sacrificial layers 122 (referring to FIG. 6). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 122 (referring to FIG. 6) are removed. Moreover, because oxidation rate of Si is much lower (sometimes 30 times lower) than oxidation rate of SiGe, the channel layers 124 and the substrate portion 112 may remain substantially intact during the channel release process.

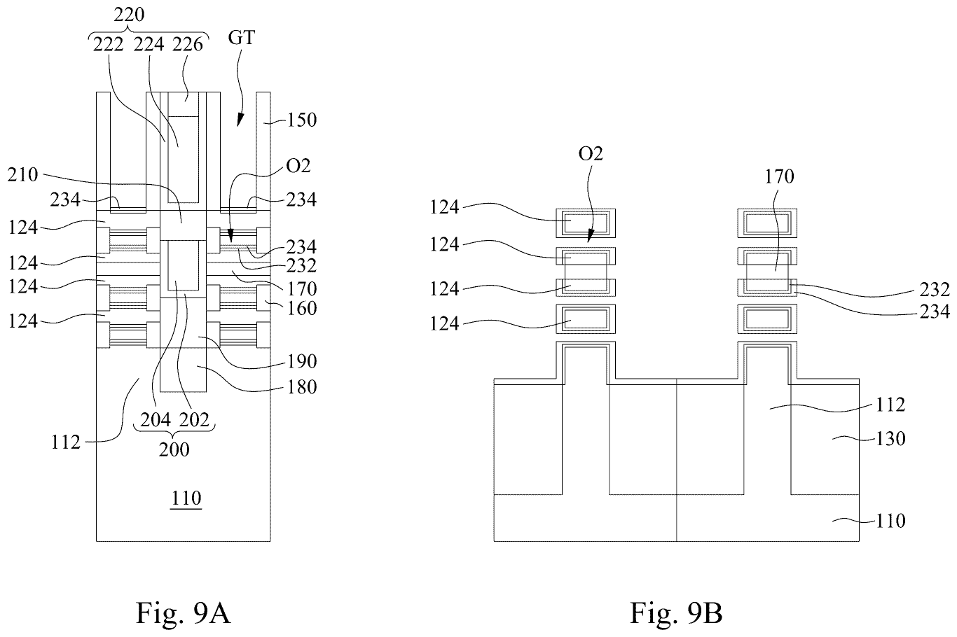

Reference is made to FIGS. 8A and 8B. A protection material S0 is selectively deposited over surfaces of the gate spacers 150, the isolation layer 170 and the inner spacers 160. The protection material S0 may be a self-assembled monolayer (SAM). In some embodiments, prior to the deposition of the protection material S0, interfacial layers 232 may be formed on surfaces of the channel layers 124. In some embodiments, the interfacial layer 232 is silicon oxide formed on exposed surfaces of semiconductor materials in the gate trenches GT by using, for example, thermal oxidation, chemical oxidation, wet oxidation or the like. As a result, surface portions of the layers 124 and the substrate portion 112 exposed in the gate trenches GT are oxidized into silicon oxide to form interfacial layer 232.

A self-assembled monolayer (SAM) refers to a single layer of molecules that spontaneously organize themselves into a highly ordered structure on a surface. This process may occur without the need for external intervention, such as heating or applying an external electric field. The molecules self-align due to interactions like van der Waals forces, hydrogen bonding, or electrostatic forces, and they form a stable, ordered monolayer. SAMs can be used to modify the surface properties of materials, such as making a surface more adhesive to specific molecules.

A self-assembled monolayer (SAM) is a one-molecule-thick layer of material that bonds to a surface in an ordered fashion through physical or chemical interactions during a deposition process. Silanes are can be used to form SAMs via vapor-phase deposition. Upon deposition, a chemical bond (such as an oxane or Si—O—M bond) forms between the silane and the surface, leading to modification of the surface properties. Long-chain alkyl silanes, which are used in SAM formation, include simple hydrocarbon, fluoroalkyl, and end-group-substituted silanes. The formation of well-ordered oxane bonds with surface hydroxyl groups (M—OH) depends on the density of these hydroxyl groups, which varies between materials.

In some embodiments, the gate spacers 150, the isolation layer 170, the inner spacers 160, and the protection material S0 having suitable materials, such that the protection material S0 has a higher affinity to the isolation layer 170, the gate spacers 150, and the inner spacers 160 than an affinity to the interfacial layer 232. For example, the protection material S0 has a higher affinity to SiOCN-like material (e.g., materials of the gate spacers, the isolation layer 170 and the inner spacers 160) than an affinity to silicon oxide (e.g., material of the interfacial layer 232). With the configuration, the protection material S0 is not deposited over surfaces of the interfacial layer 232. Stated differently, the interfacial layer 232 is free of the protection material S0.

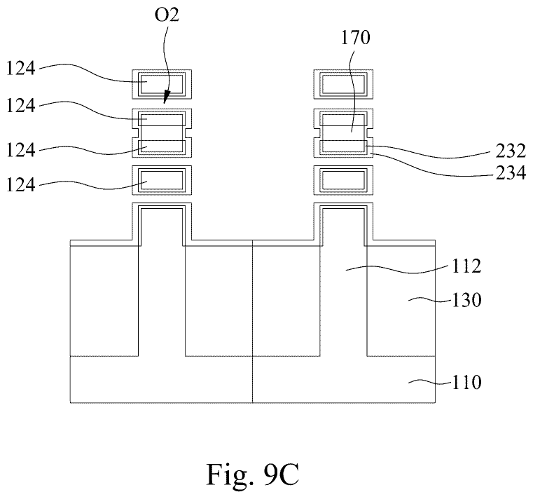

Reference is made to FIGS. 9A and 9B. A high-k dielectric layer 234 is selectively deposited to wrap over the channel layers 124. With the protection material S0 passivating surfaces of the isolation layer 170 and the inner spacers 160, the high-k dielectric layer 234 may be selectively deposited on the interfacial layer 232, and no high-k dielectric layer 234 is formed on the surfaces of the isolation layer 170, gate spacers, and the inner spacers 160, as illustrated in FIGS. 9A and 9B. In some alternative embodiments, a thin layer of high-k material may be formed on the isolation layer 170, as illustrated in FIG. 9C. In some embodiments, the protection material S0 may block a high-k dielectric precursor and make the high-k dielectric layer 234 only deposit on the interfacial layer 232, in which the surfaces of the isolation layer 170, the gate spacers 150, and the inner spacers 160 are free of the high-k dielectric layer 234. In some embodiments, the protection material S0 may cause less high-k dielectric precursor approaching on the surfaces of the isolation layer 170, the gate spacers 150, and the inner spacers 160, such that a thickness of the high-k dielectric layer 234 on the surfaces of the channel layers 124 (or the interfacial layer 232) is greater than a thickness of the high-k dielectric layer 234 on the surfaces of the isolation layer 170, the gate spacers 150 and the inner spacers 160. After the deposition of the high-k dielectric layer 234, the protection material S0 can be removed from the surfaces of the isolation layer 170 and the inner spacers 160.

In some embodiments, the high-k gate dielectric layer 234 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

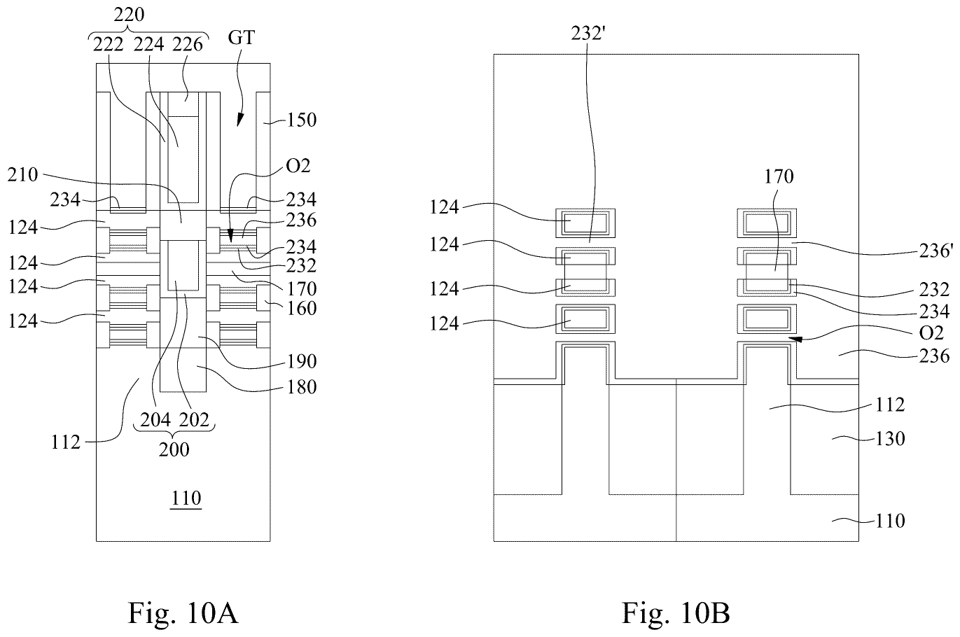

Reference is made to FIGS. 10A and 10B. A gate metal layer 236 is deposited over the high-k gate dielectric layer 234. The gate metal layer 236 may include one or more metal layers. For example, the gate metal layer 236 may include one or more work function metal layers stacked one over another and a fill metal filling up a remainder of gate trenches GT. The one or more work function metal layers in the gate metal layer 236 provide a suitable work function for the high-k/metal gate structures. For an n-type GAA FET, the gate metal layer 236 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 236 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 236 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. Formation of the gate metal layer 236 may include PVD, ALD, the like, or the combination thereof.

In some embodiments, the gate metal layer 236 may include a dummy layer 236′ between the channel layers 124 above the isolation layer 170. The dummy layer 236′ may include aluminum oxide in some embodiments.

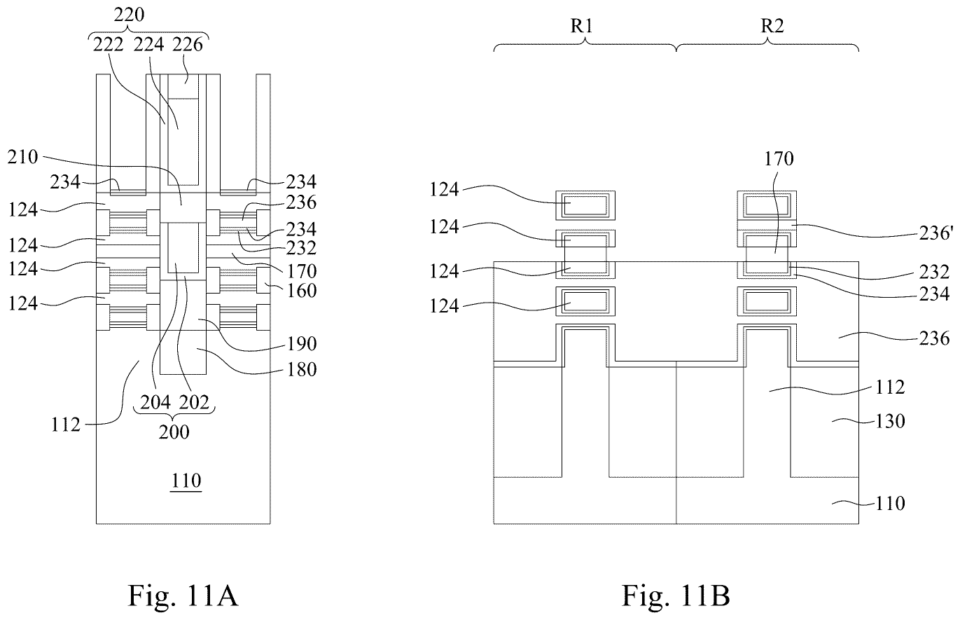

Reference is made to FIGS. 11A and 11B. An etch back process is performed to lower a top surface of the gate metal layer 236, thereby exposing the high-k dielectric layer 234 above the isolation layer 170. The etch back process may be performed such that the lowered top surface of the gate metal layer 236 is level with or lower than a bottom surface of the isolation layer 170. In some embodiments, after the etch back process, the dummy layer 236′ may remain between the channel layers 124 above the isolation layer 170.

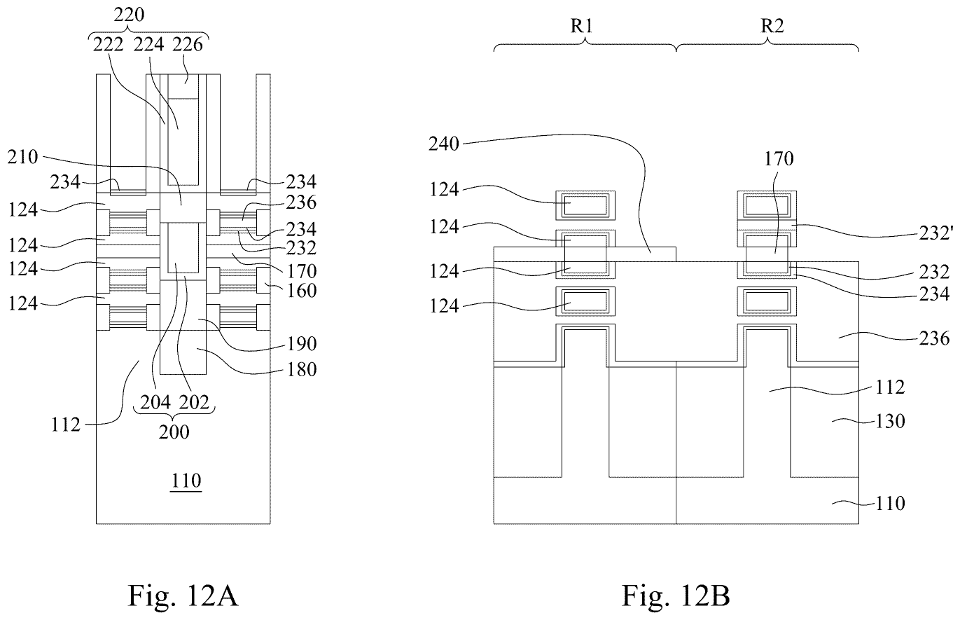

Reference is made to FIGS. 12A and 12B. A gate isolation layer 240 is formed over the top surface of the gate metal layer 236 and around the isolation layer 170. Formation of the gate isolation layer 240 may include depositing a gate isolation film over the structure of FIGS. 11A and 11B and patterning the gate isolation film into the gate isolation layer 240. After patterning process, the gate isolation layer 240 may be located at a first region R1 and expose a second region R2.

In some embodiments, the gate isolation layer 240 may include low-k dielectric materials, SiN, SiCN, SiOC, SiOCN or the like. In some embodiments, the gate isolation layer 240 may include a same material as that of the isolation layer 170. In some other embodiments, the gate isolation layer 240 may include a material different from that of the isolation layer 170. Formation of the gate isolation layer 240 may include suitable CVD, ALD process, the like, or the combination thereof. The gate isolation layer 240 may serve to isolate a metal gate for p-type transistor from a metal gate for n-type transistor.

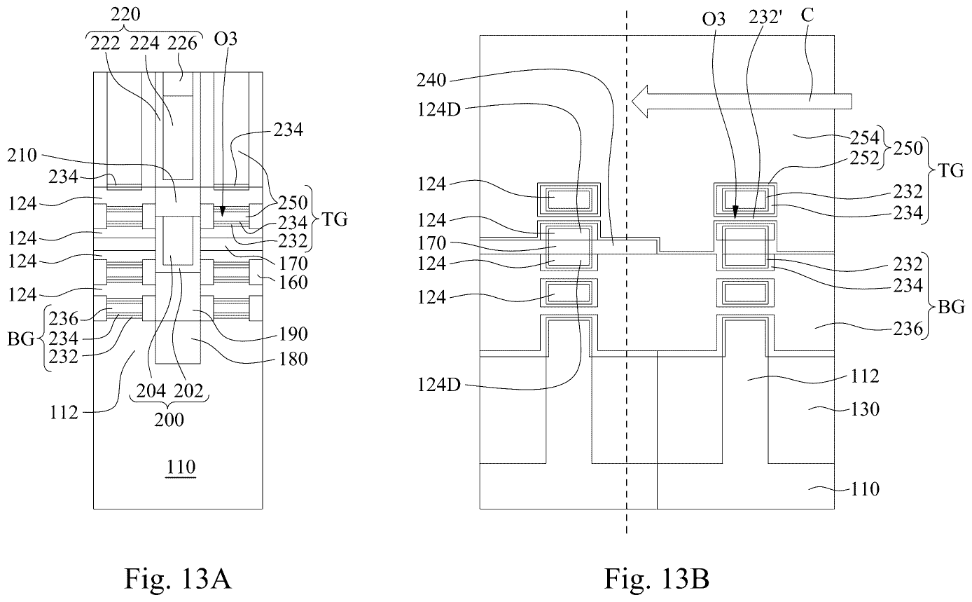

Reference is made to FIGS. 13A and 13B. A gate metal layer 250 is formed around the channel layers 124 above the isolation layer 170 and the isolation layer 240. For example, the deposition of the gate metal layer 250 may include PVD, ALD, the like, or the combination thereof.

In some embodiments, prior to the deposition of the gate metal layer 250, the dummy layer 236′ (referring to FIGS. 12A and 12B) is removed by etching process, leaving an openings/space O3 between neighboring layers 124 above the isolation layer 170. Subsequently, the gate metal layer 250 is formed in the openings/space O3 between neighboring layers 124 above the isolation layer 170. Stated differently, the dummy layer 236′ (referring to FIGS. 12A and 12B) is replaced with the gate metal layer 250.

The gate metal layer 250 may include one or more metal layers. For example, the gate metal layer 250 may include one or more work function metal layers 252 stacked one over another and a fill metal 254 filling up a remainder of gate trenches GT. The one or more work function metal layers 252 in the gate metal layer 250 provide a suitable work function for the high-k/metal gate structures. For an n-type GAA FET, the gate metal layer 250 may include one or more n-type work function metal (N-metal) layers 252. The n-type work function metal layers 252 may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, titanium nitride (TiN), tungsten (W), and/or other suitable materials. On the other hand, for a p-type GAA FET, the gate metal layer 250 may include one or more p-type work function metal (P-metal) layers 254. The p-type work function metal layers 252 may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal 254 in the gate metal layer 250 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

FIG. 13C is a cross-sectional view viewing from the direction indicated by the arrow C in FIG. 13B. Reference is made to FIGS. 13A-13C. The gate isolation layer 240 spaces the gate metal layer 250 apart from the gate metal layer 236, and also spaces the high-k dielectric layer 234 surrounding the gate metal layer 250 apart from the the high-k dielectric layer 234 surrounding the gate metal layer 236.

In some cases where the high-k dielectric layer is formed on the surfaces of the isolation layer 170, fringing field between the metal gate for p-type transistor and the metal gate for n-type transistor may go through the high-k dielectric layer on the surfaces of the isolation layer 170, which dominate total capacitance and lead to massive power degradation.

In some embodiments of the present disclosure, by selectively depositing the high-k dielectric layer 234 over the channel layers 124, little or no high-k dielectric layer 234 is formed on the surfaces of the isolation layer 170 and the inner spacers 160. With the configuration, little or no fringing field would be formed between the metal gate for p-type transistor and the metal gate for n-type transistor. As a result, the total capacitance would not be dominated by the fringing field, thereby avoiding massive power degradation.

In some embodiments, the channel layers 124 in contact with the isolation layer 170 may not be fully wrapped by the gate metal layers, and are denoted to as dummy channel layers 124D.

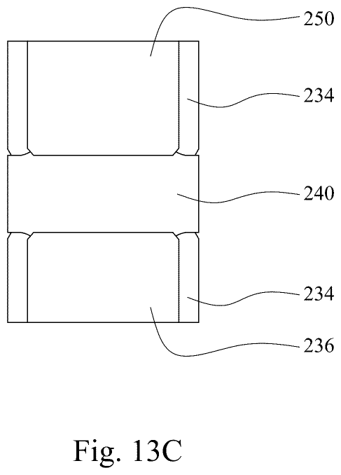

FIGS. 14A-17B illustrate schematic views of intermediate stages in the manufacture of an integrated circuit device in accordance with some embodiments of the present disclosure. FIGS. 14A, 15A, 16A, and 17A are cross-sectional views of the integrated circuit device (e.g., taken along a fin direction, e.g., cross-section A-A in FIG. 1) at various manufacturing stages in accordance with some embodiments. FIGS. 14B, 15B, 16B, and 17B are cross-sectional views of the integrated circuit device (e.g., taken along a gate direction, e.g., cross-section B-B in FIG. 1) at various manufacturing stages in accordance with some embodiments. It is understood that additional steps may be provided before, during, and after the steps shown in FIGS. 14A-17B, and some of the steps described below can be replaced or eliminated for additional embodiments of the method. The order of the operations/processes may be interchangeable.

Reference is made to FIGS. 14A and 14B. Following the steps at FIGS. 7A and 7B, interfacial layers 232 may be formed on surfaces of the channel layers 124. In some embodiments, the interfacial layer 232 is silicon oxide formed on exposed surfaces of semiconductor materials in the gate trenches GT by using, for example, thermal oxidation, chemical oxidation, wet oxidation or the like. As a result, surface portions of the layers 124 and the substrate portion 112 exposed in the gate trenches GT are oxidized into silicon oxide to form interfacial layer 232.

Subsequently, a protection material (e.g., SAM) S1 is selectively deposited over surfaces of the interfacial layer 232. The protection material (e.g., SAM) S1 has a higher affinity to the interfacial layer 232 than an affinity to the isolation layer 170, gate spacers 150, and the inner spacers 160. For example, the protection material (e.g., SAM) S1 has a higher affinity to silicon oxide (e.g., material of the interfacial layer 232) than an affinity to SiOCN-like material (e.g., materials of the gate spacers 150, the isolation layer 170 and the inner spacers 160). With the configuration, the protection material S1 is not deposited over surfaces of the isolation layer 170, the gate spacers 150, and the inner spacers 160. Stated differently, the surfaces of the isolation layer 170, the gate spacers 150, and the inner spacers 160 are free of the protection material S1.

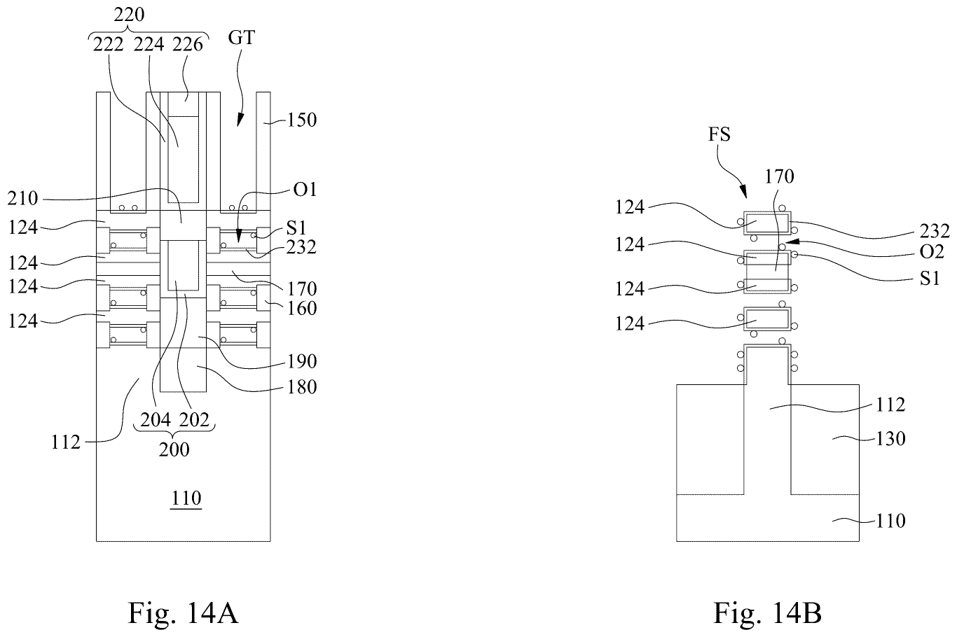

Reference is made to FIGS. 15A and 15B. After the selective deposition of the protection material S1, a protection material (e.g., SAM) S2 would be introduced to the fabrication system for deposition. The protection material S1 would block the protection material S2 from the interfacial layer 232, and thus the protection material S2 would be deposited over the surfaces of the isolation layer 170, the gate spacers 150, and the inner spacers 160. Stated differently, the surfaces of the interfacial layer 232 are free of the protection material S2.

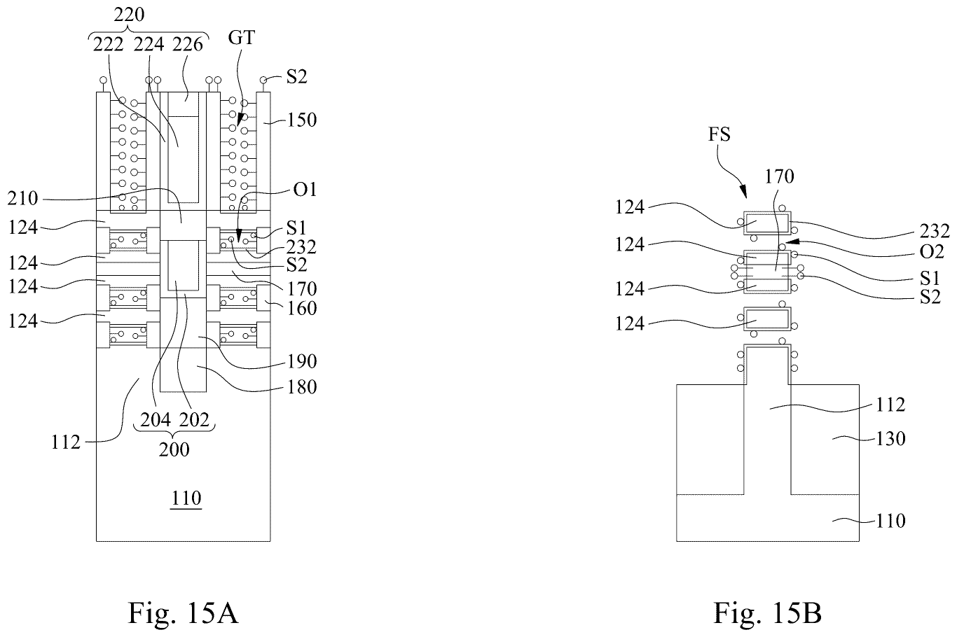

Reference is made to FIGS. 16A and 16B. After the deposition of the protection material S2, the protection material S1 (referring to FIGS. 15A and 15B) can be removed from the surfaces of the interfacial layer 232, leaving protection material S2 over the surfaces of the isolation layer 170, the gate spacers 150, and the inner spacers 160.

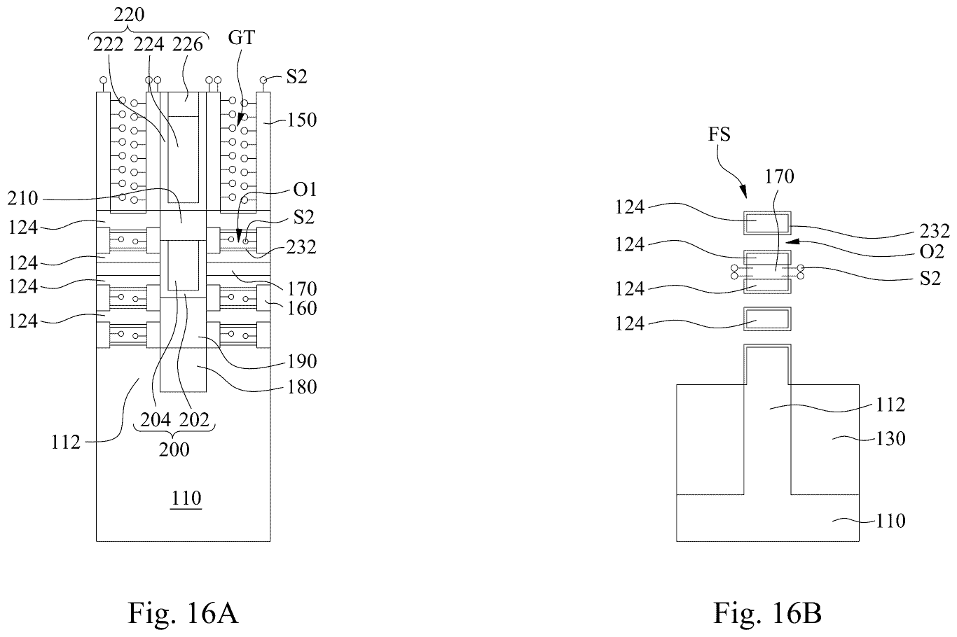

Reference is made to FIGS. 17A and 17B. A high-k dielectric layer 234 is selectively deposited to wrap over the channel layers 124. With the protection material (e.g., SAM) S2 passivating surfaces of the isolation layer 170, the gate spacers 150, and the inner spacers 160 (referring to FIGS. 16A and 16B), the high-k dielectric layer 234 may be selectively deposited on the interfacial layer 232, and little or no high-k dielectric layer 234 is formed on the surfaces of the isolation layer 170, the gate spacers 150, and the inner spacers 160. In some embodiments, the protection material S2 may block a high-k dielectric precursor and make the high-k dielectric layer 234 only deposit on the interfacial layer 232, in which the surfaces of the isolation layer 170, the gate spacers 150, and the inner spacers 160 are free of the high-k dielectric layer 234. In some embodiments, the protection material S2 may cause less high-k dielectric precursor approaching on the surfaces of the isolation layer 170, the gate spacers 150, and the inner spacers 160, such that a thickness of the high-k dielectric layer 234 on the surfaces of the channel layers 124 (or the interfacial layer 232) is greater than a thickness of the high-k dielectric layer 234 on the surfaces of the isolation layer 170, the gate spacers 150, and the inner spacers 160. After the deposition of the high-k dielectric layer 234, the protection material (e.g., SAM) S2 (referring to FIGS. 16A and 16B) can be removed from the surfaces of the isolation layer 170 and the inner spacers 160. After the formation of the high-k dielectric layer 234, the steps at FIGS. 10A-13C may be performed. Other details of the present embodiments are similar to those illustrated in FIGS. 2-13C, and thereto not repeated herein.

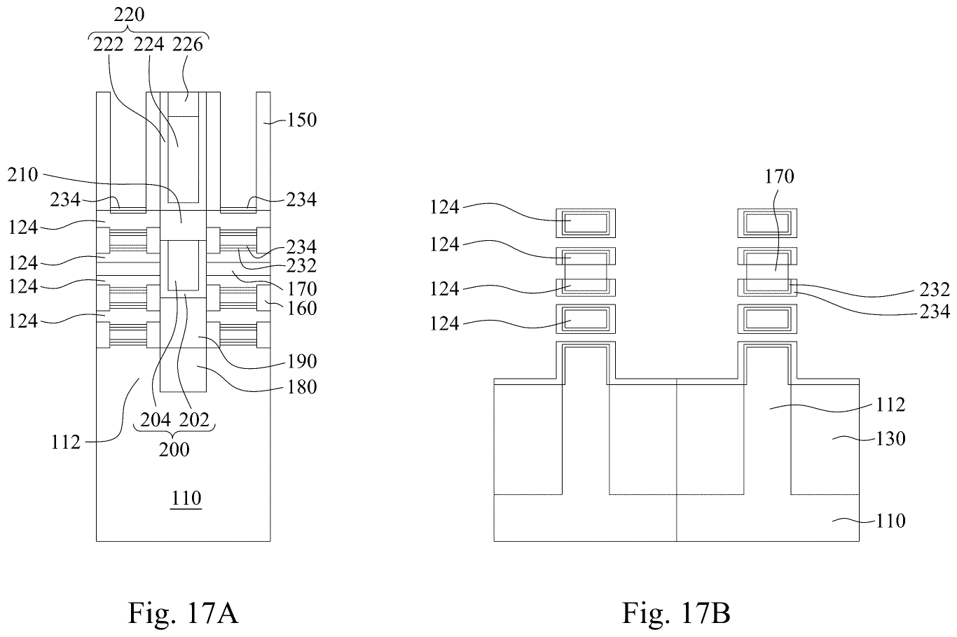

FIGS. 18A-18C are chemical formula of a protection material (e.g., SAM) S1 having a higher affinity to oxide than to SiOCN in accordance with some embodiments of the present disclosure. In FIG. 18A, the protection material (e.g., SAM) S1 is illustrated as heptamethyldisilazane. In FIG. 18B, the protection material (e.g., SAM) S1 is illustrated as a N-(Trimethylsilyl)dimethylamine. In FIG. 18C, the protection material (e.g., SAM) S1 is illustrated as carbon groups R₁ and R₂, which include long carbon chains, for example, having at least 3 carbon.

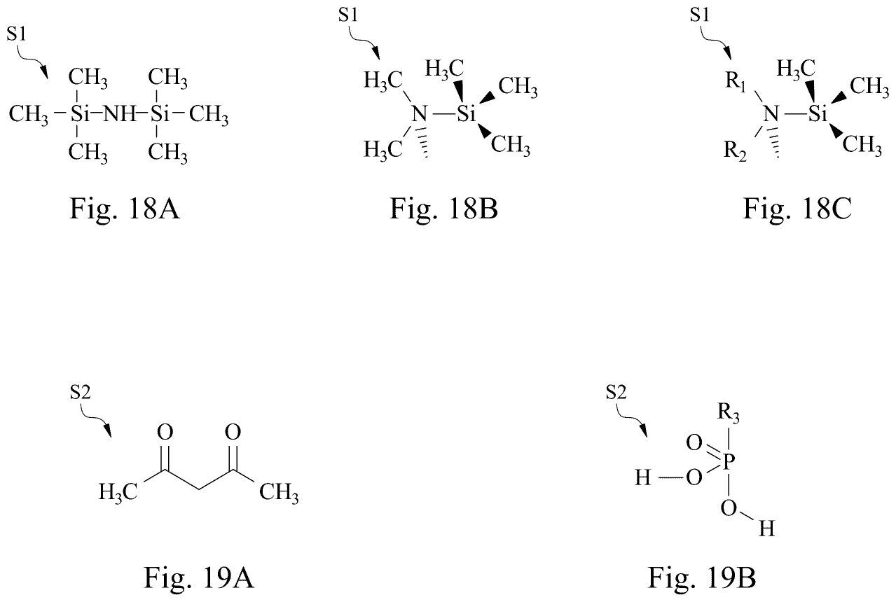

FIGS. 19A-19B are chemical formula of a protection material (e.g., SAM) S2 having a higher affinity to SiOCN than to oxide in accordance with some embodiments of the present disclosure. In FIG. 19A, the protection material (e.g., SAM) S2 is illustrated as trifluoroacetylacetone. In FIG. 19B, the protection material (e.g., SAM) S2 is illustrated as having a carbon group R₃, which may include long carbon chains, for example, having at least 8 carbon. In some embodiments, the carbon group R₃ may be an alkyl group.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by using SAM deposition, the high-k dielectric layer can be deposited on the interfacial layer, rather than on SiOCN-like material, thereby improving effective capacitance of gate isolation in CFET.

According to some embodiments of the present disclosure, a method for manufacturing an integrated circuit device is provided. The method includes forming a bottom epitaxial stack over a substrate, wherein the bottom epitaxial stack comprises at least one bottom channel layer and at least one bottom sacrificial layer; forming a middle sacrificial layer over the bottom epitaxial stack; forming a top epitaxial stack over the middle sacrificial layer, wherein the top epitaxial stack comprises at least one top channel layer and at least one top sacrificial layer; patterning the top epitaxial stack, the middle sacrificial layer, and the bottom epitaxial stack into a fin; replacing the middle sacrificial layer with a first isolation layer; removing the at least one bottom sacrificial layer and the at least one top sacrificial layer to expose surfaces of the bottom channel layer and surfaces of the top channel layer; forming a plurality of interfacial layers over the exposed surfaces of the bottom channel layer and the top channel layer; depositing a self-assembled monolayer over a surface of the first isolation layer; with the self-assembled monolayer in place, selectively depositing a high-k dielectric layer over surfaces of the interfacial layers; and depositing a first gate metal layer around the high-k dielectric layer.

According to some embodiments of the present disclosure, a method for manufacturing an integrated circuit device is provided. The method includes forming a bottom epitaxial stack over a substrate, wherein the bottom epitaxial stack comprises at least one bottom channel layer and at least one bottom sacrificial layer; forming a middle sacrificial layer over the bottom epitaxial stack; forming a top epitaxial stack over the middle sacrificial layer, wherein the top epitaxial stack comprises at least one top channel layer and at least one top sacrificial layer; patterning the top epitaxial stack, the middle sacrificial layer, and the bottom epitaxial stack into a fin; replacing the middle sacrificial layer with an isolation layer; removing the at least one bottom sacrificial layer and the at least one top sacrificial layer to expose surfaces of the bottom channel layer and surfaces of the top channel layer; forming a plurality of interfacial layers over the exposed surfaces of the bottom channel layer and the top channel layer; depositing a first self-assembled monolayer over surfaces of the interfacial layers; depositing a second self-assembled monolayer over a surface of the isolation layer, wherein the second self-assembled monolayer comprises a different material than the first self-assembled monolayer; with the second self-assembled monolayer in place, selectively depositing a high-k dielectric layer over the surfaces of the interfacial layers; and depositing a gate metal layer around the high-k dielectric layer.

According to some embodiments of the present disclosure, an integrated circuit device is provided. The integrated circuit device includes a first bottom channel layer, a second bottom channel layer, a first top channel layer, and a second top channel layer, a bottom gate metal layer, a top gate metal layer, a high-k dielectric layer, and a first isolation layer. The first bottom channel layer, the second bottom channel layer, the first top channel layer, and the second top channel layer are vertically arranged and spaced apart each other. The bottom gate metal layer surrounds the first bottom channel layer and the second bottom channel layer. The top gate metal layer surrounds the first top channel layer and the second top channel layer. The high-k dielectric layer spaces the top gate metal layer and the bottom gate metal layer apart from the first bottom channel layer, the second bottom channel layer, the first top channel layer, and the second top channel layer. The first isolation layer is between and in contact with the second bottom channel layer and the first top channel layer. A thickness of the high-k dielectric layer over a surface of the first isolation layer is less than a thickness of the high-k dielectric layer over a surface of the second bottom channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an integrated circuit device, comprising:
forming a bottom epitaxial stack over a substrate, wherein the bottom epitaxial stack comprises at least one bottom channel layer and at least one bottom sacrificial layer;
forming a middle sacrificial layer over the bottom epitaxial stack;
forming a top epitaxial stack over the middle sacrificial layer, wherein the top epitaxial stack comprises at least one top channel layer and at least one top sacrificial layer;
patterning the top epitaxial stack, the middle sacrificial layer, and the bottom epitaxial stack into a fin;
replacing the middle sacrificial layer with a first isolation layer;
removing the at least one bottom sacrificial layer and the at least one top sacrificial layer to expose surfaces of the bottom channel layer and surfaces of the top channel layer;
forming a plurality of interfacial layers over the exposed surfaces of the bottom channel layer and the top channel layer;
depositing a self-assembled monolayer over a surface of the first isolation layer;
with the self-assembled monolayer in place, selectively depositing a high-k dielectric layer over surfaces of the interfacial layers; and
depositing a first gate metal layer around the high-k dielectric layer.

2. The method of claim 1, wherein depositing the self-assembled monolayer is performed such that the self-assembled monolayer has a higher affinity to the surface of the first isolation layer than to the surfaces of the interfacial layers.

3. The method of claim 1, further comprising:
removing the self-assembled monolayer from the surface of the first isolation layer after selectively depositing the high-k dielectric layer.

4. The method of claim 1, wherein selectively depositing the high-k dielectric layer is performed such that a first thickness of the high-k dielectric layer over the surface of the first isolation layer is less than a second thickness of the high-k dielectric layer over the surfaces of the interfacial layers.

5. The method of claim 1, wherein selectively depositing the high-k dielectric layer is performed such that the surface of the first isolation layer is free of the high-k dielectric layer.

6. The method of claim 1, wherein depositing the self-assembled monolayer is performed such that the surfaces of the interfacial layers are free of the self-assembled monolayer.

7. The method of claim 1, wherein depositing the self-assembled monolayer is performed such that the self-assembled monolayer has a higher affinity to SiOCN than to silicon oxide.

8. The method of claim 1, wherein the first isolation layer comprises SiOCN.

9. The method of claim 1, further comprising:
lowering a top surface of the first gate metal layer to expose a top portion of the high-k dielectric layer;
forming a second isolation layer over the lowered top surface of the first gate metal layer and around the first isolation layer; and
depositing a second gate metal layer around the top portion of the high-k dielectric layer.

10. A method for manufacturing an integrated circuit device, comprising:
forming a bottom epitaxial stack over a substrate, wherein the bottom epitaxial stack comprises at least one bottom channel layer and at least one bottom sacrificial layer;
forming a middle sacrificial layer over the bottom epitaxial stack;
forming a top epitaxial stack over the middle sacrificial layer, wherein the top epitaxial stack comprises at least one top channel layer and at least one top sacrificial layer;
patterning the top epitaxial stack, the middle sacrificial layer, and the bottom epitaxial stack into a fin;
replacing the middle sacrificial layer with an isolation layer;
removing the at least one bottom sacrificial layer and the at least one top sacrificial layer to expose surfaces of the bottom channel layer and surfaces of the top channel layer;
forming a plurality of interfacial layers over the exposed surfaces of the bottom channel layer and the top channel layer;
depositing a first self-assembled monolayer over surfaces of the interfacial layers;
depositing a second self-assembled monolayer over a surface of the isolation layer, wherein the second self-assembled monolayer comprises a different material than the first self-assembled monolayer;
with the second self-assembled monolayer in place, selectively depositing a high-k dielectric layer over the surfaces of the interfacial layers; and
depositing a gate metal layer around the high-k dielectric layer.

11. The method of claim 10, further comprising:
removing the first self-assembled monolayer from the surfaces of the interfacial layers before selectively depositing the high-k dielectric layer.

12. The method of claim 10, further comprising:
removing the second self-assembled monolayer from the surface of the isolation layer before selectively depositing the gate metal layer.

13. The method of claim 10, wherein depositing the first self-assembled monolayer over the surfaces of the interfacial layers is performed such that the surface of the isolation layer is free of the first self-assembled monolayer.

14. The method of claim 10, wherein depositing the first self-assembled monolayer over the surfaces of the interfacial layers is performed such that the first self-assembled monolayer has a higher affinity to the surfaces of the interfacial layers than to the surface of the isolation layer.

15. The method of claim 10, wherein selectively depositing the high-k dielectric layer is performed such that a thickness of the high-k dielectric layer over the surface of the isolation layer is less than a thickness of the high-k dielectric layer over the surfaces of the interfacial layers.

16. The method of claim 10, wherein selectively depositing the high-k dielectric layer is performed such that the surface of the isolation layer is free of the high-k dielectric layer.

17. An integrated circuit device, comprising:
a first bottom channel layer, a second bottom channel layer, a first top channel layer, and a second top channel layer vertically arranged and spaced apart each other;
a bottom gate metal layer surrounding the first bottom channel layer and the second bottom channel layer;
a top gate metal layer surrounding the first top channel layer and the second top channel layer;
a high-k dielectric layer spaces the top gate metal layer and the bottom gate metal layer apart from the first bottom channel layer, the second bottom channel layer, the first top channel layer, and the second top channel layer; and
a first isolation layer between and in contact with the second bottom channel layer and the first top channel layer, wherein a thickness of the high-k dielectric layer over a surface of the first isolation layer is less than a thickness of the high-k dielectric layer over a surface of the second bottom channel layer.

18. The integrated circuit device of claim 17, wherein the surface of the first isolation layer is free of the high-k dielectric layer.

19. The integrated circuit device of claim 17, further comprising:
a second isolation layer between and in contact with the top gate metal layer and the bottom gate metal layer, wherein the second isolation layer surrounds the first isolation layer.

20. The integrated circuit device of claim 19, wherein the second isolation layer is in contact with a lower portion of the high-k dielectric layer surrounding the second bottom channel layer and an upper portion of the high-k dielectric layer surrounding the first top channel layer.
